(19) United States
(12) Patent Application Publication
(10) Pub. No.: US 2019/0035572 A1
(43) Pub. Date: Jan. 31, 2019

(54) Mobile Communication Terminal Side Button Structure

(71) Applicant: WISOL CO., LTD., Gyeonggi-do (KR)

(72) Inventors: Jung Rae NOH, Gyeonggi-do (KR); Jong Soo HA, Gyeonggi-do (KR); Yo Sep CHOI, Gyeonggi-do (KR)

(21) Appl. No.: 16/077,628

(22) PCT Filed: Feb. 16, 2017
(86) PCT No.: PCT/KR2017/001698

§ 371 Date: Aug. 13, 2018

(30) Foreign Application Priority Data
Feb. 19, 2016 (KR) 10-2016-0019613

(51) Int. Cl. H01H 13/14; H01H 13/10; H01L 41/053; H01L 41/113; H04M 1/23

(52) U.S. Cl. CPC H01H 13/14; H01H 13/10; H01L 41/053; H01L 41/113; H01H 2231/022; H01H 2201/02; H01H 2221/05; H01H 2227/016; H04M 1/236

(57) ABSTRACT

A mobile communication terminal side button structure according to an aspect of the present invention comprises: a frame having a button hole formed thereon; a button inserted into the button hole, a pressurizing protrusion being formed on the inner surface of the button; a piezoelectric element, one surface of which contacts the pressurizing protrusion; and a support member arranged on the other surface of the piezoelectric element so as to support both side edges of the piezoelectric element.

### TECHNICAL FIELD

The present invention relates to a side button structure of a mobile communication terminal, and more particularly, to a side button structure using a piezoelectric element.

### BACKGROUND

Generally, side buttons of a mobile communication terminal are installed on one side surface or both side surfaces of a terminal body and are a type of buttons capable of executing a variety of functions such as turning on/off of power, locking/unlocking of a terminal, adjusting of a volume, and the like through a user operation.

Generally, a dome switch type and a tact switch type are applied to side buttons of a mobile communication terminal.

In the dome switch type, a dome sheet, in which a dome switch is built, is attached to a flexible printed circuit board (FPCB) and the FPCB is soldered to a connection terminal formed on a main circuit board, that is, a row and column terminal pad. As the dome switch, a rubber dome switch or a metal dome switch is used.

In the tact switch type, a tact switch element is soldered to the row and column terminal pad formed on the main circuit board. These days, as the tact switch, a surface mount device (SMD), to which a surface mount technology (SMT) is applied, is used.

However, when a dome switch is used, it is necessary to manufacture an FPCB for attaching a dome sheet and to solder the FPCB to a main circuit board. Also, a fixing support is erected on a side surface of a main circuit board and fixed thereto using a double-sided adhesive tape for fixing the FPCB.

When a tact switch is used, it is necessary to surface-mount tact switches whose number corresponds to the number of side buttons on a main circuit board.

As described above, in the dome switch type, a unit price of an FPCB is high, many assembling processes are present, and a main circuit board occupies a large space for the FPCB. Also, in the tact switch type, a unit price of a tact switch is high, a surface mount cost is also high, and a main circuit board bucks a slimming-down trend of mobile communication terminals due to a thickness of the tact switch.

### SUMMARY

### Technical Problem

The present invention is directed to providing a side button structure of a mobile communication terminal having a new form using a piezoelectric element instead of a general dome switch type or a tact switch type.

### Technical Solution

According to one aspect of the present invention, a side button structure of a mobile communication terminal includes a frame which includes a button hole, a button which is inserted into the button hole and includes a pressurizing protrusion formed on an inside thereof, a piezoelectric element which has one surface in contact with the pressurizing protrusion, and a support member which is disposed on the other surface of the piezoelectric element and supports both edges of the piezoelectric element.

The support member may include a stopper protrusion which is formed at a position corresponding to the pressurizing protrusion to be spaced at a certain distance from the other surface of the piezoelectric element and restricts displacement of the piezoelectric element.

The button may include held protrusions on both inner edges, and the frame may include first holding grooves formed therein in which the held protrusions are accommodated.

The side button structure may further include a plate spring which is provided between the button and the piezoelectric element and elastically supports the button.

The plate spring may elastically support the held protrusions.

The plate spring may include a hole corresponding to an inner surface of the button and may include a protrusion portion formed inside the hole at a part of an inner circumferential surface of the hole corresponding to the held protrusion such that the protrusion portion may elastically support the held protrusion.

The frame may include second holding grooves formed therein in which edges of the plate spring are accommodated.

The button may include a waterproofing member on an outer circumference thereof corresponding to the button hole.

According to another aspect of the present invention, a side button structure of a mobile communication terminal includes a frame which includes a button hole, a button which is inserted into the button hole and includes a pressurizing protrusion formed on an inside thereof, a piezoelectric element which has one surface in contact with the pressurizing protrusion, and a plate spring which is provided between the button and the piezoelectric element and elastically supports the button.

The button may include held protrusions on both inner edges, and the frame may include first holding grooves formed therein in which the held protrusions are accommodated.

The plate spring may elastically support the held protrusions.

The plate spring may include a hole corresponding to an inner surface of the button and may include a protrusion portion formed inside the hole at a part of an inner circumferential surface of the hole corresponding to the held protrusion such that the protrusion portion may elastically support the held protrusion.

The frame may include second holding grooves formed therein in which edges of the plate spring are formed.

The side button structure may further include a support member which is disposed on the other surface of the piezoelectric element, supports both edges of the piezoelectric element, and includes a stopper protrusion which is formed at a position corresponding to the pressurizing protrusion to be spaced at a certain distance from the other surface of the piezoelectric element and restricts displacement of the piezoelectric element.

The button may include a waterproofing member on an outer circumference thereof corresponding to the button hole.

### Advantageous Effects

According to the present invention, side buttons of a mobile communication terminal may be embodied to be felt like being integrated with or being a part of a side frame of the mobile communication terminal and may be embodied to be operable using a pressure or a touch instead of “pushing” on a button such as an existing dome switch type or tact switch type.

In addition, the side buttons of the mobile communication terminal may function as not only input means but also means which give a user feedback by generating vibrations by applying electric signals to piezoelectric elements.

Also, a piezoelectric element is advantageous in cost due to a low cost thereof and has advantages of having a simple structure, having a simple assembling process, being easily miniaturized, and providing a slim structure of the mobile communication terminal.

### BRIEF DESCRIPTION OF THE DRAWINGS

FIG. 1 is an exploded perspective view of a side button structure of a mobile communication terminal according to one embodiment of the present invention when viewed from one side.

FIG. 2 is an exploded perspective view of the side button structure of the mobile communication terminal according to one embodiment of the present invention when viewed from the other side.

FIG. 3 is a cross-sectional view the side button structure of the mobile communication terminal according to one embodiment of the present invention.

FIG. 4 is a perspective view illustrating buttons 200 and a plate spring 300 when viewed from one side.

FIG. 5 is a perspective view illustrating the buttons 200 and the plate spring 300 when viewed from the other side.

### DETAILED DESCRIPTION

Hereinafter, exemplary embodiments of the present invention will be described in detail with reference to the attached drawings. In the following description and the attached drawings, substantially like elements are referred to as like reference numerals such that a repetitive description will be omitted. In the description of the present invention, a detailed description on well-known functions or components of the related art will be omitted when it is deemed to obscure the essence of the present invention.

A side button structure of a mobile communication terminal according to one embodiment of the present invention uses a piezoelectric element. The piezoelectric element is an element which uses a piezoelectric effect. When the piezoelectric element is deformed by applying an external force (or a touch) thereto, electric polarizability occurs such that an electric potential is generated. On the other hand, when a voltage is applied thereto, the piezoelectric element is deformed or gains a stress.

A button using a piezoelectric element senses an external force and generates an electrical signal so as to function as input means and to generate vibrations by applying the electrical signal to the piezoelectric element so as to give a feedback to the user.

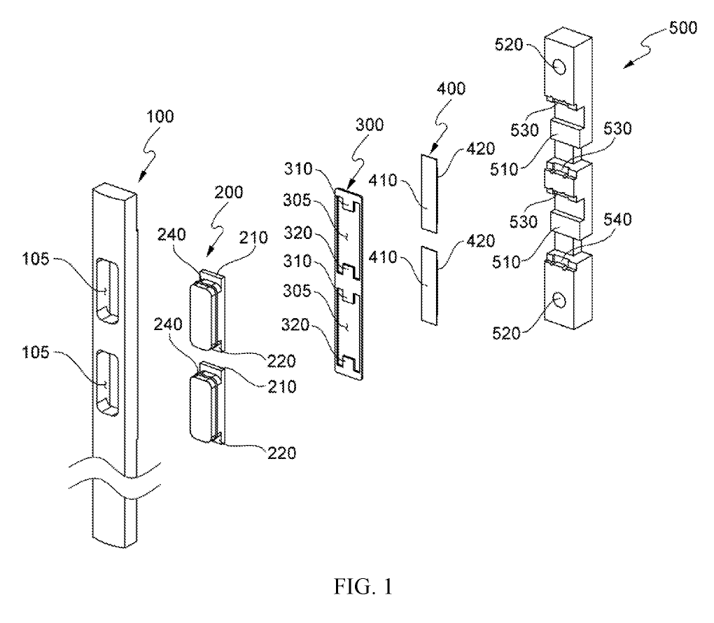

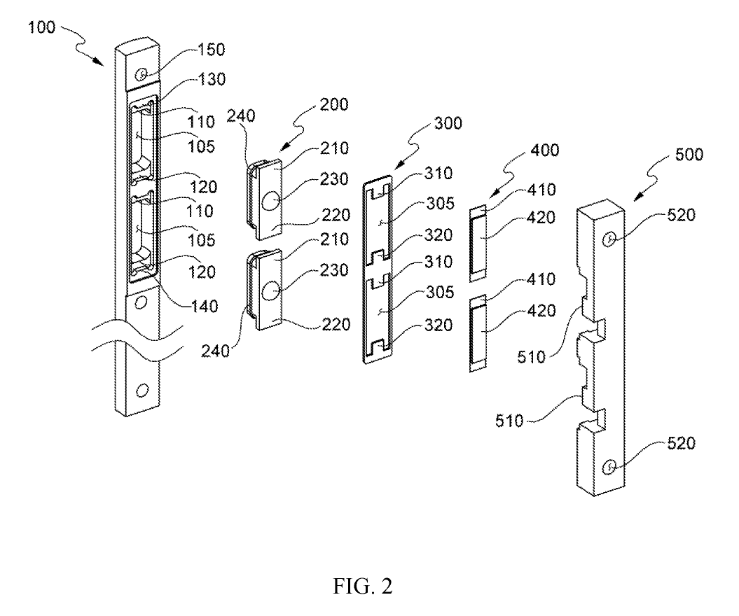

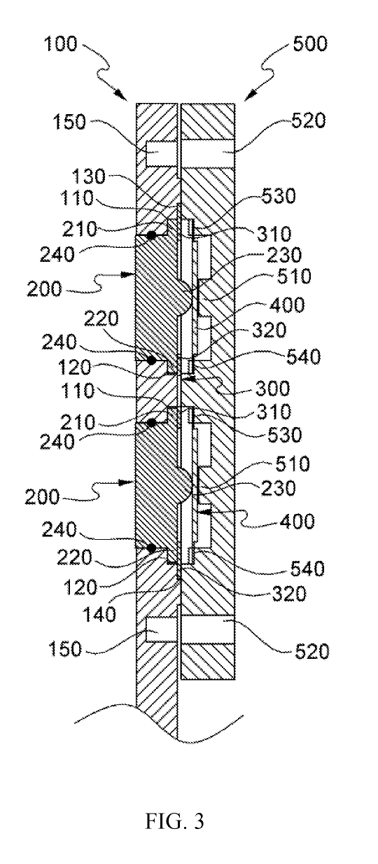

FIGS. 1 to 3 are views illustrating a side button structure according to one embodiment of the present disclosure. FIG. 1 is an exploded perspective view when viewed from one side, FIG. 2 is an exploded perspective view when viewed from the other side, and FIG. 3 is a cross-sectional view.

Referring to FIGS. 1 to 3, the side button structure according to the embodiment includes a frame 100, buttons 200, a plate spring 300, piezoelectric elements 400, and a support member 500.

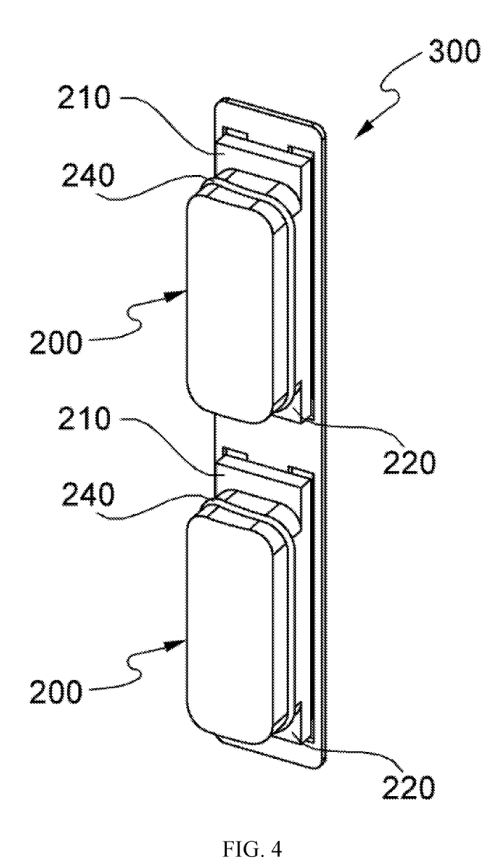

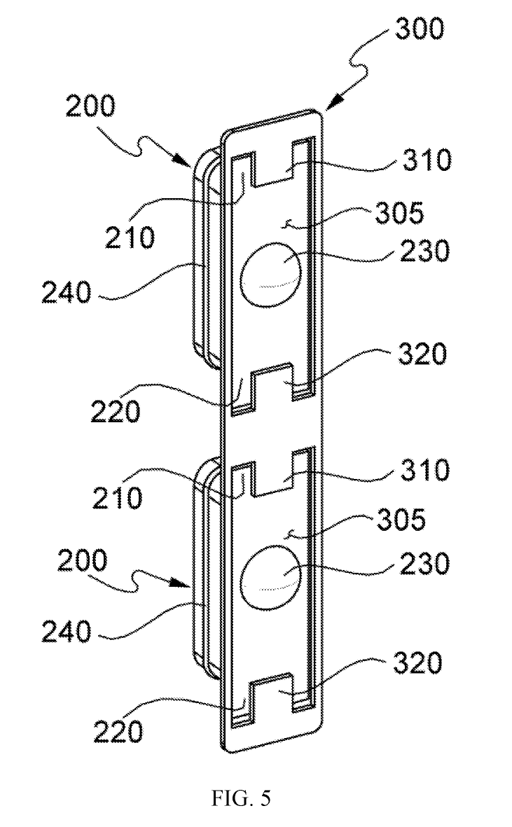

FIGS. 4 and 5 separately illustrate the buttons 200 and the plate spring 300. FIG. 4 is a perspective when viewed from one side, and FIG. 5 is a perspective view when viewed from the other side.

In the embodiment of the present invention, it is described as an example that there are two buttons 200. However, one or more buttons 200 may be present.

The frame 100 may be a housing or a case of the mobile communication terminal or may be a part of the housing or the case. The frame 100 may correspond to a side of the mobile communication terminal. Here, “the side” of the mobile communication terminal means a side surface, a top surface, or a bottom surface of the mobile communication terminal. The frame 100 may include a metal or a synthetic material.

The frame 100 includes button holes 105 formed in a side thereof such that the buttons 200 are inserted into the button holes 105.

An outer surface of the button 200 may be flush with the side of the frame 100 or may slightly protrude more than the side of the frame 100. Hereby, it is possible to allow a user to feel the button 200 like being integrated with the frame 100 or being a part of the frame 100.

To allow the button be supported by the frame 100, the button 200 may include held protrusions 210 and 220, which protrude from both inner edges of the button 200, and the frame 100 may include first holding grooves 110 and 120, in which the held protrusions 210 and 220 of the button 200 are accommodated, on both edges of a button hole 105 in the frame 100. Due to the held protrusions 210 and 220 and the first holding grooves 110 and 120, the button 200 does not deviate outward from the frame 100.

The button 200 includes a pressurizing protrusion 230 in a central portion of an inner surface, and the pressurizing protrusion 230 may be disposed to come into contact with a central portion of one surface of the piezoelectric element 400 which will be described below. Accordingly, when the user applies an external force to the button 200, the external force is transferred to the piezoelectric element 400 through the pressurizing protrusion 230. On the other hand, when vibrations of the piezoelectric element 400 occur, the vibrations may be transferred to the button 200 through the pressurizing protrusion 230 and the user who touches the button 200 may feel the vibrations.

Also, for waterproofing of the button 200 and the button hole 105, the button 200 may include a groove formed in an outer circumference corresponding to the button hole 105 and a waterproofing member 240 such as waterproof sealing may be configured to be accommodated in the groove. Depending on embodiments, the groove in which the waterproofing member 240 is accommodated may be formed not only in the outer circumference of the button 200 but also in an inner circumference of the button hole 105.

The piezoelectric element 400 includes a plate 410 and a piezoelectric body 420 attached to one surface (or both surfaces) of the plate 410. Generally, the plate 410 is a metallic material, for example, a stainless material and has a larger area than the piezoelectric body 420. The piezoelectric body 420 may be manufactured using a material having an excellent piezoelectric property such as quartz, tourmaline, Rochelle salt, barium titanate, monoammonium phosphate, tartaric acid ethylenediamine, and the like.

The piezoelectric element 400 includes first and second outer electrodes (not shown). The first and second outer electrodes may be connected to a circuit device of the mobile communication terminal through a conducting wire or a flexible printed circuit board (FPCB) on which a conducting wire is formed. When the piezoelectric element 400 is deformed, the circuit device of the mobile communication terminal may detect an external force or a touch by measuring voltages detected through the first and second outer electrodes. On the other hand, the circuit device of the mobile communication terminal may cause vibrations to the piezoelectric element 400 by applying an electrical signal to the first and second outer electrodes.

The support member 500 is disposed on the other surface of the piezoelectric element 400, that is, a side opposite to the button 200 on the basis of the piezoelectric element 400 and supports both edges of the piezoelectric element 400. Support grooves 530 and 540, which support both edges of piezoelectric element 400 (in detail, both edges of the plate 410) are formed in the support member 500, and the both edges of the piezoelectric element 400 may be attached to the support grooves 530 and 540 using an adhesive.

The support member 500 may include a stopper protrusion 510 which is formed at a position corresponding to the pressurizing protrusion 230 of the button 200 to be spaced at a certain distance apart from the other surface of the piezoelectric element 400 and restricts inward displacement of the piezoelectric element 400. Here, a distance between an inner surface of the piezoelectric element 400 and the stopper protrusion 510 may be, for example, 10 to 30 μm. That is, the stopper protrusion 510 may restrict the inward displacement of the piezoelectric element 400 within a range of 10 to 30 μm. However, the other surface of the piezoelectric element 400 and the stopper protrusion 510 may be determined as an adequate value according to properties of the piezoelectric element 400, a degree of pressure to be sensed, and the like, and the present invention is not limited thereto.

Meanwhile, the frame 100 includes combination holes 150 and the support member 500 includes through holes 520 at positions corresponding to the combination holes 150 of the frame 100 such that the frame 100 and the support member 500 may be combined with each other by combination members (for example, screws) which pass through and penetrate the through holes 520 and the combination holes 150.

The plate spring 300, which is disposed between the buttons 200 and the piezoelectric elements 400, elastically supports the buttons 200. The plate spring 300 may be formed of an elastic metal material or a synthetic resin material. The plate spring 300 may support the button 200 from the inside simultaneously while providing an elastic force to the button 200 toward the outside by using a restoration force of the plate spring 300 when a pressure is applied to the button 200. Accordingly, when the pressure applied to the button 200 is released, the button 200 returns to an original position.

In detail, an outer circumference of the plate spring 300 may be larger than the inner surfaces of the buttons 200 which includes the held protrusions 210 and 220 and may include holes 305 corresponding to the inner surfaces of the buttons 200 therein. For example, the holes 305 may be formed to be slightly larger than the inner surfaces of the buttons 200 (except protrusion portions 310 and 320 which will be described below) such that the buttons are inserted therein. Also, the protrusion portions 310 and 320 are formed inside the holes 305 at parts corresponding to the held protrusions 210 and 220 in inner circumferences of the holes 305 such that the protrusion portions 310 and 320 may elastically support the held protrusions 210 and 220 of the buttons 200. That is, the protrusion portions 310 and 320 of the plate spring support the held protrusions 210 and 220 of the button 200 simultaneously while the held protrusions 210 and 220 of the button 200 push the protrusion portions 310 and 320 of the plate spring 300 such that the protrusion portions 310 and 320 are deformed when a pressure is applied to the button 200. Here, restoration forces occur at the protrusion portions 310 and 320.

In order to accommodate the plate spring 300, in an inside of the frame 100, second holding grooves 130 and 140, in which edges of the plate spring 300 are accommodated, may be formed outside the first holding grooves 110 and 120.

According to the present invention, side buttons of a mobile communication terminal may be embodied to be felt like being integrated with or being a part of a side frame of the mobile communication terminal and may be embodied to be operable using a pressure or a touch instead of “pushing” on a button such as an existing dome switch type or tact switch type.

In addition, the side buttons of the mobile communication terminal may function as not only input means but also means which give a user feedback by generating vibrations by applying electric signals to piezoelectric elements.

Also, a piezoelectric element is advantageous in cost due to a low cost thereof and has advantages of having a simple structure, having a simple assembling process, being easily miniaturized, and providing a slim structure of the mobile communication terminal.

The exemplary embodiments of the present invention have been described above. It will be understood by one of ordinary skill in the art that modifications may be made without departing from the essential properties of the present invention. Therefore, the disclosed embodiments should be considered in a descriptive aspect not a limitative aspect. The scope of the present invention is defined by the claims not by the above description, and it should be understood that all differences within the equivalents thereof are included in the present invention.

What is claimed is:

1. A side button structure of a mobile communication terminal, comprising:
a frame which comprises a button hole;
a button which is inserted into the button hole and comprises a pressurizing protrusion formed on an inside thereof;
a piezoelectric element which has one surface in contact with the pressurizing protrusion; and
a support member which is disposed on the other surface of the piezoelectric element and supports both edges of the piezoelectric element.

2. The side button structure of claim 1, wherein the support member comprises a stopper protrusion which is formed at a position corresponding to the pressurizing protrusion to be spaced at a certain distance from the other surface of the piezoelectric element and restricts displacement of the piezoelectric element.

3. The side button structure of claim 1, wherein the button comprises held protrusions on both inner edges, and
wherein the frame comprises first holding grooves formed therein in which the held protrusions are accommodated.

4. The side button structure of claim 3, further comprising a plate spring which is provided between the button and the piezoelectric element and elastically supports the button.

5. The side button structure of claim 4, wherein the plate spring elastically supports the held protrusions.

6. The side button structure of claim 5, wherein the plate spring comprises a hole corresponding to an inner surface of the button and comprises a protrusion portion formed inside the hole at a part of an inner circumferential surface of the hole corresponding to the held protrusion such that the protrusion portion elastically supports the held protrusion.

7. The side button structure of claim 4, wherein the frame comprises second holding grooves formed therein in which edges of the plate spring are accommodated.

8. The side button structure of claim 1, wherein the button comprises a waterproofing member on an outer circumference thereof corresponding to the button hole.

9. A side button structure of a mobile communication terminal, comprising:
a frame which comprises a button hole;
a button which is inserted into the button hole and comprises a pressurizing protrusion formed on an inside thereof;
a piezoelectric element which has one surface in contact with the pressurizing protrusion; and
a plate spring which is provided between the button and the piezoelectric element and elastically supports the button.

10. The side button structure of claim 9, wherein the button comprises held protrusions on both inner edges, and
wherein the frame comprises first holding grooves formed therein in which the held protrusions are accommodated.

11. The side button structure of claim 10, wherein the plate spring elastically supports the held protrusions.

12. The side button structure of claim 11, wherein the plate spring comprises a hole corresponding to an inner surface of the button and comprises a protrusion portion formed inside the hole at a part of an inner circumferential surface of the hole corresponding to the held protrusion such that the protrusion portion elastically supports the held protrusion.

13. The side button structure of claim 10, wherein the frame comprises second holding grooves formed therein in which edges of the plate spring are accommodated.

14. The side button structure of claim 9, further comprising a support member which is disposed on the other surface of the piezoelectric element, supports both edges of the piezoelectric element, and comprises a stopper protrusion which is formed at a position corresponding to the pressurizing protrusion to be spaced at a certain distance from the other surface of the piezoelectric element and restricts displacement of the piezoelectric element.

15. The side button structure of claim 9, wherein the button comprises a waterproofing member on an outer circumference thereof corresponding to the button hole.
